(19) United States
(12) Patent Application Publication
(10) Pub. No.: US 2015/0136358 A1
(43) Pub. Date: May 21, 2015

(54) COOLING ELEMENT

(71) Applicant: ABB Oy, Helsinki (FI)

(72) Inventors: Thomas GRADINGER, Aarau Rohr (CH); Bruno Agostini, Zurich (CH)

(73) Assignee: ABB Oy, Helsinki (FI)

(21) Appl. No.: 14/547,760

(22) Filed: Nov. 19, 2014

(30) Foreign Application Priority Data
Nov. 20, 2013 (EP) 13193615.5

(51) Int. Cl. H05K 7/20

(52) U.S. Cl. CPC H05K 7/20154; H05K 7/20409
USPC 165/80.3

(57) ABSTRACT

A cooling element includes a first surface for receiving an electric component, and a second surface which is provided with fins for forwarding a heat load received from the electric component via the first surface to surroundings. One or more of the fins are provided with a respective flow channel for passing a fluid within each respective fin, to provide efficient cooling.

### RELATED APPLICATION

This application claims priority to European Application 13193615.5 filed in Europe on Nov. 20, 2013. The entire content of this application is hereby incorporated by reference in its entirety.

1. Field of the Disclosure

The present disclosure relates to a cooling element, and more particularly, to a cooling element for cooling an electric component.

2. Background Information

There is a known cooling element with a first surface for receiving an electric component. A second surface of the cooling element is provided with fins for forwarding a heat load received from the electric component via the first surface to surroundings via the fins.

Cooling elements of this type may be installed in a horizontal orientation, though other orientations are also possible. A horizontal orientation refers to an orientation where the first surface faces upwards, while the cooling fins protrude downwards. A channel for an airflow may in that case be located between the fins, in other words below the electric component that is attached to the first surface.

However, such a cooling element has an insufficient cooling performance. In particular, when used in combination with power-semiconductor modules generating significant heat loads during use, it is difficult to ensure a sufficient cooling for the electric component.

### SUMMARY

An exemplary embodiment of the present disclosure provides a cooling element which includes a first surface configured to receive an electric component thereon, and a second surface having fins configured to forward a heat load received from the electric component via the first surface to surroundings. At least one of the fins has a flow channel for passing a fluid within the at least one fin, respectively. The flow channel has a capillary dimension and a meandering shape for providing a pulsating heat pipe.

### BRIEF DESCRIPTION OF DRAWINGS

Additional refinements, advantages and features of the present disclosure are described in more detail below with reference to exemplary embodiments illustrated in the drawings, in which:

FIGS. 1a and 1b illustrate the working principle of a pulsating heat pipe,

FIG. 2 illustrates an exemplary embodiment of a cooling element according to the present disclosure;

FIG. 3 illustrates an exemplary embodiment of a fin according to the present disclosure;

FIGS. 4 and 5 illustrate an exemplary embodiment of a fin according to the present disclosure; and

FIGS. 6 and 7 illustrate an exemplary embodiment of a cooling element according to the present disclosure.

### DETAILED DESCRIPTION

Exemplary embodiments of the present disclosure solve the drawbacks associated with known techniques as noted above by providing a cooling element with improved capabilities. According to an exemplary embodiment, the cooling element includes, in part, fins having respective flow channels for passing a fluid within the fins.

The use of a cooling element with fins having flow channels for passing a fluid makes it possible to obtain a cooling element with improved cooling capabilities.

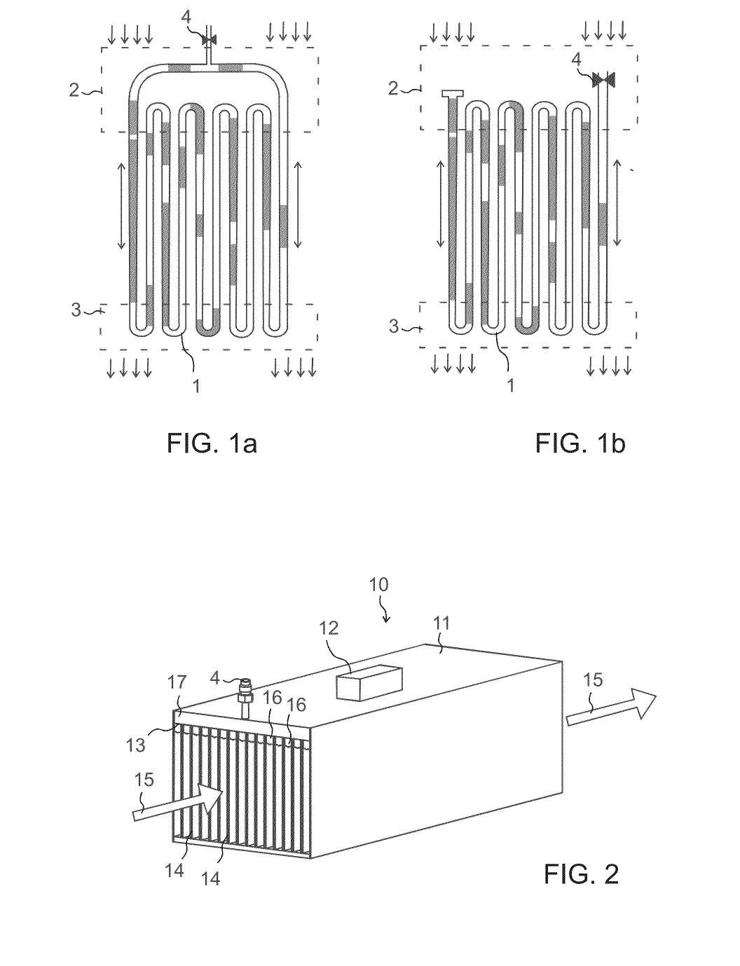

FIGS. 1a and 1b illustrate the working principle of a Pulsating Heat Pipe (PHP) according to an exemplary embodiment of the present disclosure. FIG. 1a illustrates a closed-loop PHP and FIG. 1b illustrates an open-loop PHP.

A pulsating heat pipe involves a meandering flow channel 1 having a capillary dimension, in other words a cross-section small enough for capillary forces to dominate over gravity forces. A suitable fluid can be introduced into the flow channel 1 via a filling valve 4. As a consequence, the fluid is moved by pulsations generated by pressure instabilities. The oscillations occur in a small channel loop due to the bidirectional expansion of vapor inside the channels. During operation, the liquid slugs and elongated vapor bubbles will oscillate between a cold and a hot region because of hydrodynamic instabilities caused by the rapid expansion of the bubbles confined in the small channels, and thus provide a fluid velocity almost independent of gravity. This makes pulsating heat pipes fairly insensitive to orientation, with the possibility of operating them “upside down”, e.g., with an evaporator 2 on top and a condenser 3 at the bottom.

An advantage of utilizing a pulsating heat pipe in a cooling element is that the cooling element can be utilized in any orientation without causing problems for fluid circulation within the cooling element.

FIG. 2 illustrates an exemplary embodiment of a cooling element 10 according to the present disclosure. The cooling element 10 includes a first surface 11 for receiving an electric component 12, such as a power-semiconductor module, which may be attached to the first surface with screws, for example. One alternative is that the cooling element 10 is a part of a motor drive, such as a frequency controller, controlling supply of electricity to an electric motor. In that case, the electric component 12 may be an IGBT (Insulated Gate Bipolar Transistor) module, for example.

A second surface 13 of the cooling element 10 is provided with fins 14 for forwarding a heat load received from the electric component 12 to surroundings (e.g., ambient environment) via the fins 14. In the illustrated example, the fins 14 are implemented as elongated plates like elements protruding downwards from the second surface 13 of the cooling element 10. Spacers 16 may be arranged between the fins and in contact with the second surface 13 in order to obtain gaps between the fins. An airflow 15 may be generated to pass between the fins 14 such that the fins dissipate heat into this airflow 15.

In order to obtain an efficient cooling element 10, one or more of the fins 14 are provided with a flow channel 1 for passing a fluid within each respective fin 14. According to an exemplary embodiment, each fin 14 has a flow channel; however, in some implementations, it may be sufficient to have flow channels only in some of the fins 14. According to an exemplary embodiment, the flow channels 1 of the different fins 14 may be in fluid communication with each other so that the flow channel 1 of each fin does not need to be filled separately. Such a fluid communication may be obtained via the base plate 17 to which the electric component 12 is attached and to which the fins 14 are thermally connected. In such a configuration, one single filling valve 4 arranged in the first surface of the base plate 17 may be used for introducing fluid into all of the fins 14.

An advantage obtained by having fluid channels in the fins 14 is that a more efficient distribution of heat load to different parts of the fins is achieved. Consequently, a significant area of the fins can be efficiently utilized for dissipating heat to surroundings, as the fluid in the fluid channel 1 efficiently transfers heat between different parts of the fins 14.

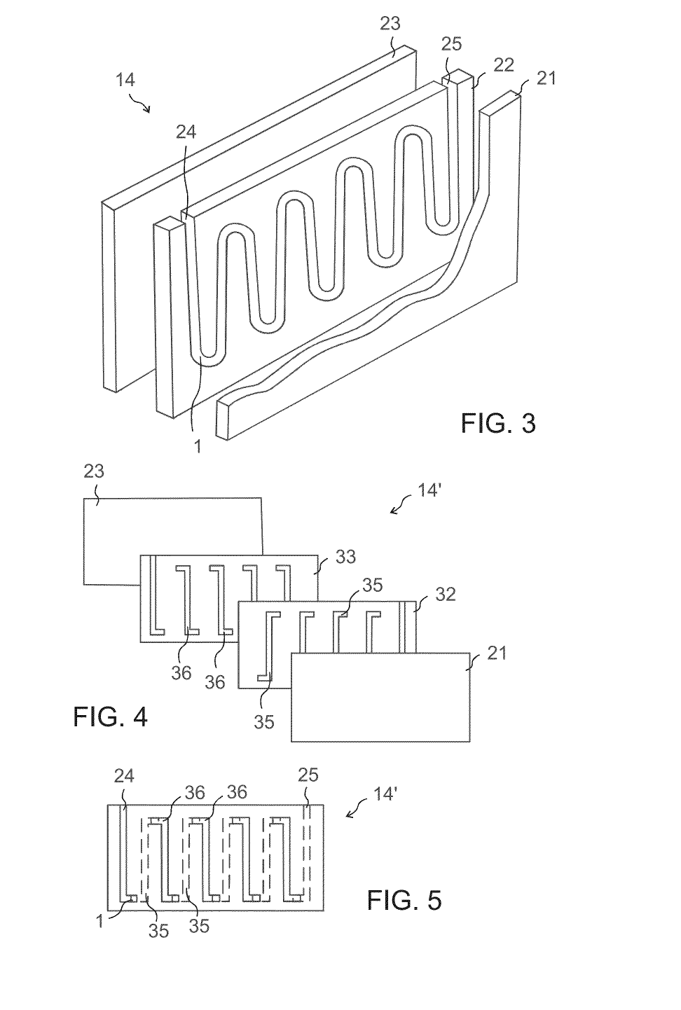

FIG. 3 illustrates an exemplary embodiment of a fin 14 according to the present disclosure. The fins used in the embodiment of FIG. 2 may be implemented as illustrated in FIG. 3.

The illustrated fin 14 includes a stack of plates 21 to 23 arranged against (e.g., next to) each other. The middle plate 22 has a slit which works as the fluid channel 1 distributing fluid to different parts of the fin 14. This slit may be manufactured by punching or cutting, for example. According to an exemplary embodiment, the two outer plates 21 and 23 are non-perforated solid plates which provide fluid tight outer walls for the fin 14 on opposite sides of the middle plate 22.

The fin 14 has two openings 24 and 25 on opposite ends of the flow channel 1. The openings 24 and 25 are arranged in a side edge of the fin 14 which faces the second surface 13 of the cooling element 10. These openings facilitate a fluid communication between the fluid channel 1 of the fin 14 and other parts of the cooling element.

If fluid circulation within the flow channel 1 should be obtained without the need of an external device, such as a pump, and independently of the orientation of the cooling element, the flow channel 1 may be capillary dimensioned in order to get the fins of the cooling element to work as a pulsating heat pipe. One way to determine whether or not the fluid channel has a capillary dimension is to calculate the Eötvös number, which should be below about 4. Eötvös number EÖ can be calculated as follows:

EÖ=(D·(g(p_{liq}−pᵥₐₚ)/σ)^{0.5})²

wherein D is the channel hydraulic diameter, g is the gravitational acceleration, pliq is the liquid density, pvap is the vapour density, and σ is the surface tension.

For refrigerant R245fa (1,1,1,3,3-Pentafluoropropane), which may be used as the fluid, a possible choice is a conduit height (i.e., sheet thickness of the middle plate 22) of 1 mm and a conduit width (i.e., width of slit in the middle plate 22) of 2 mm, for example. This results in Eö=2.2 at a fluid operating temperature of 60° C., as shown in the table below:

| | | |
|---|---|---|
| conduit width | 2 | mm |
| conduit height | 1 | mm |
| conduit cross-sectional area | 2 | mm² |
| conduit perimeter | 6 | mm |
| conduit hydraulic diameter | 1.33 | mm |
| gravitational acceleration | 9.81 | m/s² |
| type of fluid | R245fa | |
| operating temperature | 60 | ° C. |
| liquid density | 1′237 | kg/m³ |
| vapor density | 25.7 | kg/m³ |
| surface tension | 9.6 | mN/m |
| Bond number | 1.48 | |
| Eotvos number | 2.20 | |

FIGS. 4 and 5 illustrate an exemplary embodiment of a fin 14′ according to the present disclosure. The embodiment of FIGS. 4 and 5 is similar to the one explained in connection with FIG. 3. Therefore, the embodiment of FIGS. 4 and 5 will be explained mainly by pointing out the differences between these embodiments. The illustrated fin 14′ may be utilized in a cooling element 10 of FIG. 2, for example.

From FIG. 4, which illustrates the parts of the fin 14′ before assembly, it can be seen that the fin 14′ includes two middle plates 33 and 34 instead of only one middle plate in the embodiment of FIG. 3. The first 33 and second 34 middle plates both include a plurality of separate slits 35 and 36 shaped and located in such positions that the slits 35 and 36 of the first middle plate 33 and the second middle plate 34 will together form the fluid channel 1 once the plates are stacked against each other.

FIG. 5 illustrates the plates 32 and 33 stacked against each other. From FIG. 5, it can be seen that the slits 35 and 36 of the first and second middle plates partly overlap each other such that a continuous fluid channel 1 is provided through the fin 14′, similar to the embodiment of FIG. 3. Similarly, as in FIG. 3, openings 24 and 25 are arranged in a side edge of the fin 14′ which faces the second surface 13 of the cooling element 10.

An advantage obtained with the embodiment of FIGS. 4 and 5 as compared to the embodiment of FIG. 3 is that the middle plates 32 and 33 are each formed of only one single part, which makes it easier to handle them during manufacturing, for example. In FIG. 3, the slit forming the fluid channel 1 cuts the middle plate into two separate parts, which needs to be located in correct positions during manufacturing.

In order to ensure that the fin 14′ and the fluid channel 1 works as a pulsating heat pipe with the same fluid as explained in FIG. 3, the thickness of the first and second middle plates 32, 33 may each be 1 mm, for example. The thickness of the outer plates 21 and 23 may be 0.5 mm each, for example.

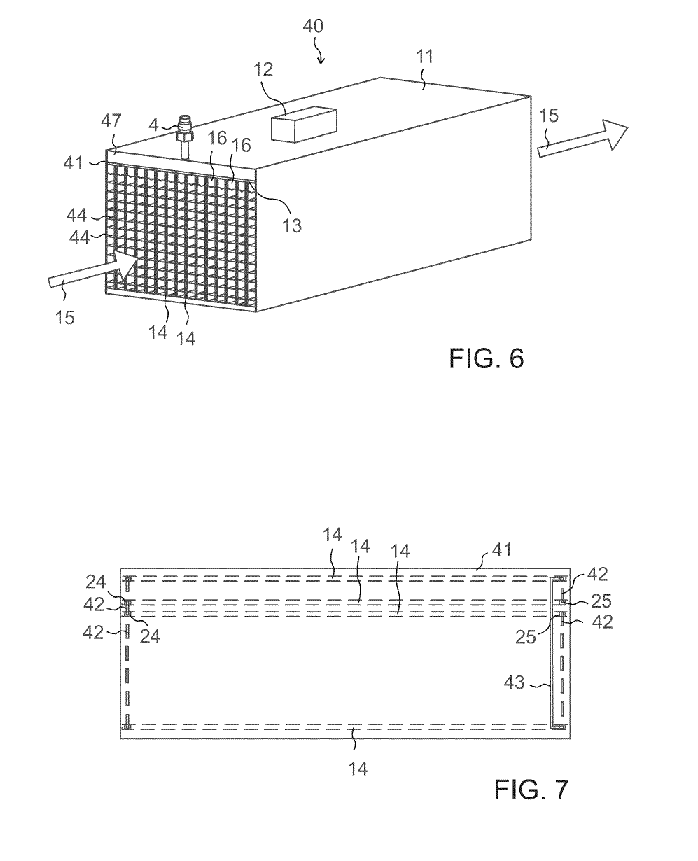

FIGS. 6 and 7 illustrate an exemplary embodiment of a cooling element 40 according to the present disclosure. The embodiment of FIGS. 6 and 7 is similar to the one explained in connection with FIG. 2. Therefore, the embodiment of FIGS. 6 and 7 is explained mainly by pointing out the differences between these embodiments

Similar to the embodiment of FIG. 2, the fins 14 may be of the type illustrated in FIG. 3 or of the type illustrated in FIGS. 4 and 5. In the embodiment of FIGS. 6 and 7, secondary fins 44 are provided to extend between the illustrated fins 14. Such secondary fins 44, which increase the surface area dissipating heat into the airflow 15, may also be utilized in the embodiment of FIG. 2.

In the embodiment of FIGS. 6 and 7, the cooling element 40 includes a first plate 47 and a second plate 41 stacked against each other such that the first surface 11 for receiving an electric component 12 and the second surface 13 provided with fins 14 are facing opposite directions (i.e., arranged transverse to one another).

FIG. 7 illustrates the second plate 41 in more detail. The second plate working as a connector plate is provided with through holes 42 at the locations of the openings 24 and 25 of the fins 14. In FIG. 7, only four fins 14 are illustrated for simplicity. As can be seen from FIG. 7, the holes 42 in the second plate are arranged and dimensioned such that two fins 14 are located at each hole 42, and one opening 24 of two adjacent fins 14 are in fluid communication via the hole 42 in question. Consequently, the holes 42 provide fluid communication between the fluid channels 1 of the different fins. Due to this, the fluid channel of the different fins may be connected to a single closed loop working as a pulsating heat pipe. The first plate 47 may be implemented as a solid base plate that does not need to have any other fluid channels than possibly a bore for the filling valve 4. The first plate 47 provides a fluid tight roof on top of the second plate 42, and the second surface 13 (bottom surface in FIG. 6) of the second plate 41 is prevented from leakage by the fins 14 and the spacer elements 16.

FIG. 7 illustrates that the second plate 41 is also provided with an elongated slit 43 which provides fluid communication between one respective opening of the two fins 14 which are located as far away from each other as possible. This elongated slit 43, extending completely through the second plate 41, is not necessary in all embodiments. If it is present, the result is (provided that dimensioning of the fluid channel is correct) a closed loop pulsating heat pipe, and if it is not present, the result is an open loop pulsating heat pipe.

As is clear from the previous explanations, the incorporation of a pulsating heat pipe into the cooling element makes it possible to obtain a cooling element with efficient cooling capabilities and which can be used in any position necessary. Such an orientation independent cooling element can be directly used to replace a known cooling element which does not include any fluid circulation in the fins, because the cooling element can be arranged in any position, also in a position where the first surface with the electric component is directed upwards and the fins are directed downwards.

The production of the described cooling element can be accomplished by preparing metal plates of suitable size, by providing a solder at the locations where the parts should be attached to each other. After this, the cooling element can be assembled and placed in an oven where it is heated to the melting point of the solder. Once removed from the oven, the parts attach firmly to each other while they are allowed to cool.

It is to be understood that the above description and the accompanying figures are only intended to illustrate exemplary embodiments of the present disclosure. It will be obvious to a person skilled in the art that the present disclosure can be varied and modified without departing from the scope of the disclosure.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A cooling element comprising:
a first surface configured to receive an electric component thereon; and
a second surface having fins configured to forward a heat load received from the electric component via the first surface to surroundings,
wherein at least one of the fins has a flow channel for passing a fluid within the at least one fin, respectively, the flow channel having a capillary dimension and a meandering shape for providing a pulsating heat pipe.

2. The cooling element according to claim 1, wherein a plurality of the fins each have a respective flow channel provided therein, the flow channels of the fins being in fluid communication with each other.

3. The cooling element of claim 2, comprising:
a common inlet for introducing fluid to the fluid channels of the fins.

4. The cooling element of claim 1, wherein:
one of the fins comprises a stack of plates including a middle plate and two outer plates; and
the fluid channel of the one of the fins includes a slit in the middle plate, and the two outer plates are arranged on opposite sides of the middle plate to provide fluid tight side walls of the fluid channel.

5. The cooling element of claim 1, wherein:
one of the fins comprises a stack of plates including a first middle plate, a second middle plate, and two outer plates;
the fluid channel of the one of the fins includes a plurality of separate slits provided in the first and second middle plates such that the slits in the first and second middle plates partly overlap each other to provide a continuous fluid channel through the one of the fins; and
the two outer plates are arranged on opposite sides of the first and second middle plates to provide fluid tight side walls of the fluid channel.

6. The cooling element of claim 1, comprising:
a first plate with the first surface for receiving the electric component; and
a second plate with the second surface having the fins, wherein:
the second plate is stacked against the first plate such that the first and second surfaces are facing opposite directions;
the at least one fin provided with the flow channel comprises two respective openings in opposite ends of the respective flow channel, the openings facing the second plate; and
the second plate includes through holes at locations of the openings such that one opening of two adjacent fins are in fluid communication with each other via one through hole provided in the second plate.

7. The cooling element of claim 1, comprising:
a first plate with the first surface for receiving the electric component, and
a second plate with the second surface having the fins, wherein:
the second plate is stacked against the first plate such that the first and second surfaces are facing opposite directions;
the at least one fin provided with the flow channel comprises two respective openings in opposite ends of the respective flow channel, the openings facing the second plate;
the second plate includes through holes at locations of the openings such that one opening of two adjacent fins are in fluid communication with each other via one through hole provided in the second plate; and
the second plate is provided with an elongated slit providing fluid communication between one respective opening of the two fins which are located farthest away from each other.

8. The cooling element of claim 1, comprising:
secondary fins extending between the fins provided on the second surface.

9. The cooling element of claim 4, comprising:
secondary fins extending between the fins provided on the second surface.

10. The cooling element of claim 5, comprising:
secondary fins extending between the fins provided on the second surface.

11. The cooling element of claim 6, comprising:
secondary fins extending between the fins provided on the second surface.

12. The cooling element of claim 7, comprising:
secondary fins extending between the fins provided on the second surface
